(19) United States
(12) Patent Application Publication
(10) Pub. No.: US 2006/0016963 A1
(43) Pub. Date: Jan. 26, 2006

(54) Medical sensors

(76) Inventor: Benjamin Maytal, Mevasseret Zion (IL)

Correspondence Address: DANIEL J SWIRSKY, 55 REUVEN ST., BEIT SHEMESH, 99544, IL

(21) Appl. No.: 11/145,172

(22) Filed: Jun. 6, 2005

Related U.S. Application Data
(60) Provisional application No. 60/577,494, filed on Jun. 7, 2004.

(51) Int. Cl. H03F 3/08

(52) U.S. Cl. 250/214 A

(57) ABSTRACT

A medical sensor includes a CMOS (complementary metal-oxide semiconductor) photo detecting sensor array with a sensitivity and SNR (signal to noise ratio) sufficient for medical purposes and a processing unit to generate an output signal indicating the amount of light impinging on said photo sensor array. The sensitivity is at least 10 bits and the SNR is at least 70 dB.

### CROSS-REFERENCE TO RELATED APPLICATIONS

This application claims benefit from U.S. Provisional Patent Application No. 60/577,494, filed Jun. 7, 2004, which is hereby incorporated by reference.

### FIELD OF THE INVENTION

The present invention relates to medical sensors generally.

### BACKGROUND OF THE INVENTION

Medical light sensors are known. Some of them utilize the transmission of light through a body tissue having blood vessels to non-invasively measure important health indicators, such as heart rate, blood pressure and blood oxygen level. Another example of the use of such sensors is “light printing”, in which returned light measurements are used for personal identification, such as for identifying a unique handprint.

An exemplary, prior art, medical sensor 10 using light measurement technology is shown in FIG. 1, to which reference is now made. Light 14 is transmitted from LEDs 20 into skin tissue 24 in which blood vessels 12 are located. Light of varying wavelengths such as red light (e.g. 660 nm), as indicated by arrow 16, and infrared light (e.g. 940 nm), as indicated by arrow 18 are used. The blood cells in blood vessels 12 absorb the light differently depending on the concentration of hemoglobin in the blood. The measurement of light transmitted through the tissue or reflected from the tissue can indicate the oxygen level at a certain time and continuous measurements over a period of time can yield the heart rate, blood pressure and average oxygen levels in the blood. Other medical measurements such as blood alcohol levels, glucose levels and body fat, can also be measured using this technology.

Reference is now made to FIG. 2 which illustrates medical sensor 10 in more detail. As can be seen, medical sensor 10 comprises a multiplicity of photo detectors 32 which perform the measurements, connected in series to a current to voltage transformer 34, an analog to digital converter 36 and a storage unit 38. Unfortunately, photo detectors 32 are expensive and space consuming. The device requires separate components 34, 36 and 38, typically connected externally to photo detectors 32. Moreover, the device consumes power continuously while measurements are being taken.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a schematic illustration of a prior art medical sensor;

FIG. 2 is a partial block diagram illustration of the sensor of FIG. 1;

FIG. 3 is a block diagram illustration of a novel, photo detecting medical sensor, constructed and operative in accordance with the present invention;

FIG. 4 is a schematic illustration of a sensor array, forming part of the sensor of FIG. 3;

FIG. 5 is a circuit diagram illustration of a pixel of the sensor array of FIG. 4;

FIG. 6A is a schematic illustration of a plurality of photo detecting diodes such as can be used for the pixel of FIG. 5, each tuned to a different frequency of light; and

FIG. 6B is a schematic illustration of an IR photo detecting diode such as can be used for the pixel of FIG. 5.

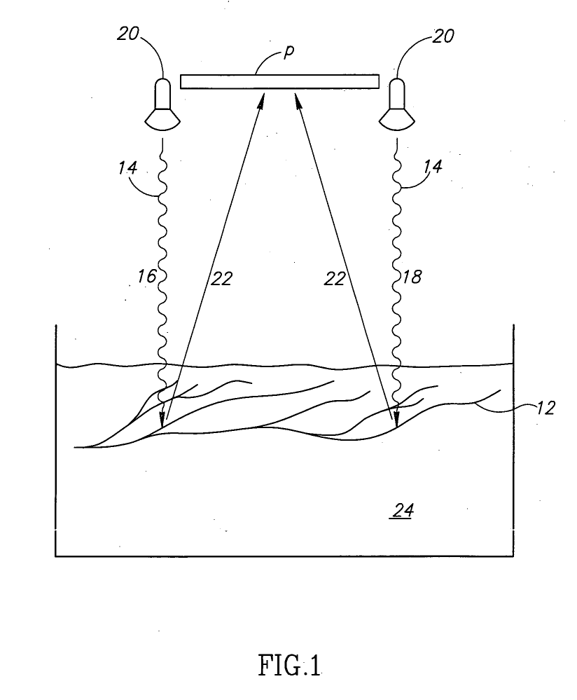

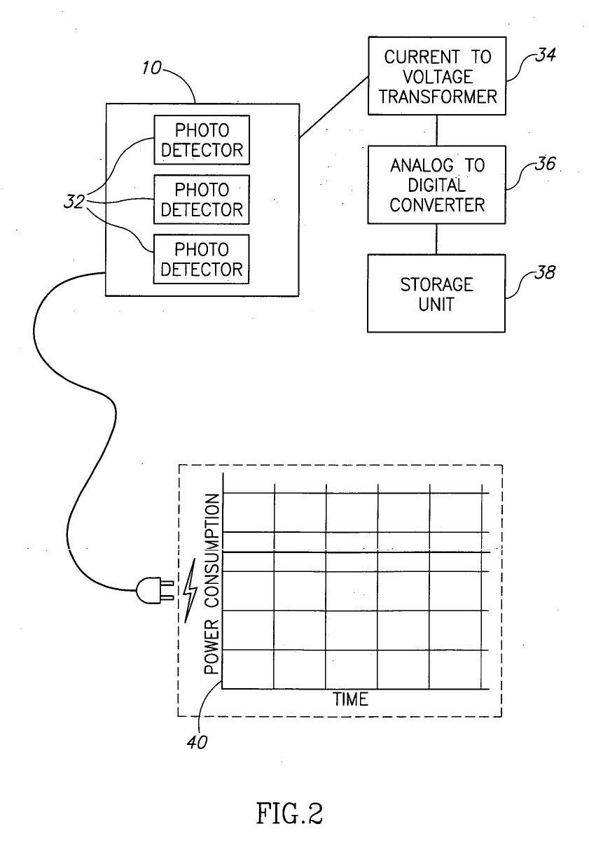

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

Applicant has realized that VLSI (very large scale integration) CMOS (complementary metal-oxide semiconductors) image sensors may be implemented for medical sensors. Doing so may provide significant size and cost reduction benefits.

Such CMOS image sensors, integrated onto a wafer like any VLSI component, are generally cheaper and smaller than photo detectors 32 and are typically used in cameras for imaging. Unlike photo detectors 32, which measure the amount of light of a specific wavelength impinging on a given area, cameras image a scene and indicate the shades and color of light across the scene. Typically, cameras have pixels of about 5 μm² each. For camera usage, a large number of pixels (e.g. 1 million) are used. Each pixel typically contains a photo sensitive diode which discharges a capacitor or capacitive element. The sensitivity of CMOS image sensors is typically 6 bits and the signal to noise ratio (SNR) is 40 db. However, current CMOS image sensor technology is not sufficient for medical photo detection which requires a sensitivity of at least 10 bits and an SNR of at least 70 db.

Applicant has realized that the CMOS image sensor may be changed for medical photo detection in a number of ways. The sensitivity to light of the CMOS image sensor may be increased by increasing the size of the component pixels. Alternatively or in addition, the output of multiple pixels may be averaged for a single measurement. The structure of the photo diode may be changed to more advantageously respond to incident light.

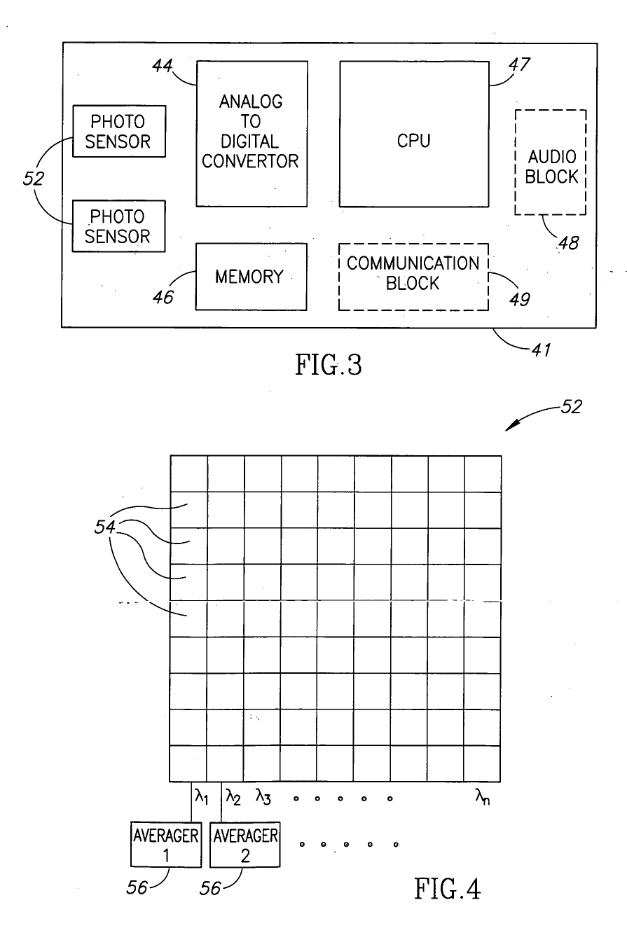

Reference is now made to FIG. 3, which illustrates the elements of an innovative medical sensor 50, constructed and operative in accordance with a preferred embodiment of the present invention. Medical sensor 50 may comprise a multiplicity of photo sensors 52 (two are shown), an analog to digital converter 54, an on-chip memory 56 and a CPU 58. In alternative embodiments of the present invention, sensor 50 may also comprise a communication block 55 and/or an audio block 57.

As described in more detail hereinbelow, photo sensors 52 may measure incident light and may generate a voltage signal in response thereto. Analog-to-digital converter 54, such as are well known in the art, may convert the voltage signal to a digital signal which may be processed by CPU 58. The results may be stored in on-chip memory 56.

CPU 58 may check the results against ranges of acceptable measured values for each type of measurement (e.g. heart rate, oxygen level, etc.). When the measurements may be outside of this range, CPU 58 may issue an alarm sound and may send an alarm message.

Medical sensor 50 may be used for monitoring purposes, which may require continuous measurements. Several measurements may be required for a single reported measurement (e.g. measurement of oxygen level may last 20 seconds but may require 20 measurements for a reliable result.) CPU 58 may operate medical sensor 50 briefly during the measurement time (e.g. 1 msec) and may be shut off until the next measurement. This may reduce the amount of power utilized.

Communication block 55 may be any suitable communication device, such as one which may communicate via any standard communication technology, such as infrared, Bluetooth, Wlan etc., and may provide the results generated by CPU 58 to an external device, such as a monitor. Audio block 57 may provide such results in an audio manner. Alternatively, audio block 57 may generate status sounds to indicate the status of the device, such as on/off, an error, etc.

It will be appreciated that medical sensor 50 may be manufactured as a single chip, thereby significantly lowering the cost of such sensors. Medical sensor 50 may be operated with no-battery technologies, such as hand movement charging, solar batteries and/or thermoelectric devices utilizing body heat. Certain elements of such technologies, such as the charge booster and the control for the thermoelectric device, may be integrated inside the chip.

Reference is now made to FIG. 4, which details one photo sensor 52. Photo sensor 52 may comprise a multiplicity of CMOS photo pixels 54, arranged in an array, for light intensity measurements. In a preferred embodiment of the present invention, photo pixels 54 may have an at least 10 times larger area than pixels of current CMOS image sensors, thereby to respond to a greater amount of light with less noise. Thus, pixels 54 may be approximately 50-200 μm².

To further reduce noise, the output of multiple CMOS sensor pixels 54 may be averaged together for a single measurement. For example, white noise may be reduced by 3 dB for every factor of two pixels combined together. In the embodiment of FIG. 4, the output of each column of the array may be connected together and averaged in an associated averager 56. Averager 56 may be a separate unit or part of CPU 58.

In accordance with a preferred embodiment of the present invention, each column or group of columns of photo sensor 54 may be tuned to a different frequency λᵢ of light. In one embodiment, each column may be covered with a light filter attuned to the desired frequency λᵢ of light. For example, for red, the light filter may pass light above of 600-660 nm.

For example, photo pixels 54 may be covered with a red, green or blue light filter. Red, blue and green light passing these filters may be measured directly. For any other color in the visible range, a combination of the measurements through the filters may be used.

Infrared light passes through the filters with no disturbance, and may be measured separately or simultaneously with red light. As a separate measurement, it may be measured using any filter or with no filter. Alternatively, the intensity of the infrared light may be measured by a non-infra-red (e.g. green) pixel together with measurement of an infra- red pixel. The infra-red intensity may be determined by CPU 54 by subtracting the green pixel measurement from the red pixel measurement. If desired, a calibration may be performed before the measurements to account for ambient light.

Reference is now made to FIG. 5, which details one photo pixel 54. Pixel 54 may comprise a diode 60, a reset transistor 62, a charge transfer transistor 64 and a row select transistor 66. Reset transistor 62 may be controlled by a RESET signal and may transfer a Vdd level charge to a node 68 when activated.

Diode 60 may also be connected to node 68 and may comprise an n-well 63. Diode 60 may be separated from other diodes by p-wells 65. Diode 60 may discharge the charge at node 68 in the presence of light, typically during an “integration period”. At the end of the integration period, the level of charge at node 68, which may be correlated to the light intensity, may be measured.

Node 68 may control charge transfer transistor 64, which may receive a Vdd supply level and be connected in series with row select transistor 66. At the beginning of the integration period, the charge level at node 68 may be high, which may be sufficient to fully activate charge transfer transistor 64 to transfer most, if not all, of Vdd supply to the input of row select transistor 66. However, as integration continues, diode 60 may utilize some of the charge at node 68, thereby reducing the charge of node 68 and thus, slightly turning off charge transfer transistor 64. The more light seen by diode 60, the less the charge will be at node 68 and therefore, the less charge transferred to the input of row select transistor 66.

When the ROW SELECT signal may be activated, typically at the end of the integration period, if at all, row select transistor 66 may transfer whatever charge there is to a column 70. It will be appreciated that column 70 may combine the outputs of a multiplicity of pixels 54 (which may have an averaging effect) and may provide such outputs to its associated averager 56 which may divide the output by the number of pixels in the column. It will be appreciated that, instead of a column, the output of a row may be combined together.

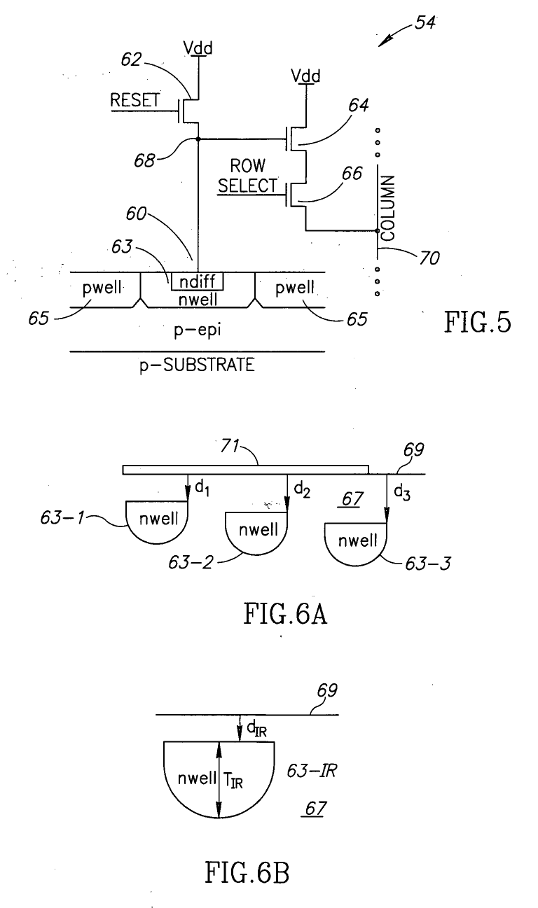

Reference is now made to FIGS. 6A and 6B, which illustrate two implementations of diode 60 for absorbing different wavelengths of light, one (FIG. 6A) for absorbing different wavelengths of visible light and one (FIG. 6B) for absorbing infrared (IR) light.

In FIG. 6A, n-well 63 may be buried within a silicon substrate 67 at varying distances dᵢ, dⱼ and dₖ from a surface 69 of the silicon substrate. As shown in FIG. 6A, n-well 63-1 may be buried at a distance of d₁ within silicon substrate 67 while n-well 63-2 may be buried at a distance d₂ and n-well 63-3 may be buried at a distance d₃. Each n-well 63 may be sensitive to light of a different wavelength λᵢ, where the longer the wavelength, the deeper the light may penetrate, or:
dᵢf=(e^{λ}^{ᵢ})

For infrared light, which has a longer wavelength, of about 900 nm, n-well 63-IR may be a deeper n-well (i.e. have a larger well depth T_{IR}) as shown in FIG. 6B, than those for visible light. N-well 63-IR may be implanted from a distance d_{IR} from surface 69 until a depth d_{IR}+T_{IR}, where d_{IR}=0-2 μm and T_{IR}=1-4 μm. This may result in increased sensitivity to the infrared range.

It will be appreciated that, in addition to the n-wells 63 at variable distances, sensitivity to different wavelengths of light may be increased by depositing filters 71 over the surfaces 69 where n-wells 63 may be implanted.

Returning to FIG. 4, different columns of photo sensor 52 may be sensitive to different wavelengths of light. This may implemented with filters 71, with n-wells at variable distances or both, as desired. The light impinging on photo sensor 52 may be provided either by a single white LED, which may provide multiple wavelengths or several LEDs, of different colors, may be used.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A medical sensor comprising:
a CMOS (complementary metal-oxide semiconductor) photo detecting sensor array with a sensitivity and SNR (signal to noise ratio) sufficient for medical purposes; and
a processing unit to generate an output signal indicating the amount of light impinging on said photo sensor array.

2. The sensor of claim 1 and wherein said sensitivity is at least 10 bits and said SNR is at least 70 dB.

3. The sensor according to claim 1 and wherein said photo sensor array comprises a plurality of pixels, each having a photo diode formed of an n-well implanted in a substrate.

4. The sensor according to claim 3 and wherein said pixels are divided into groups and each group is tuned to measure light of a different wavelength.

5. The sensor according to claim 4 and wherein said n-well is implanted at a distance d from a surface of said substrate, where d is a function of said wavelength.

6. The sensor according to claim 3 and wherein said n-well has a depth of 1-4 μm for measuring infrared light.

7. The sensor according to claim 4 and wherein at least one group comprises a filter over said substrate to pass light of said wavelength to said n-well.

8. The sensor according to claim 3 and wherein each said pixel has a minimal area of 50 μm².

9. The sensor according to claim 3 and wherein the output of a line of said array is combined together.

10. The sensor according to claim 9 and wherein said output is averaged.

11. The sensor according to claim 1 and wherein said photo sensor array and said processing unit are formed on a single chip.

12. The sensor according to claim 11 and wherein said processing unit comprises at least an analog-to-digital converter, a central processing unit (CPU) and a memory unit.

13. The sensor according to claim 12 and wherein said processing unit also comprises at least one of: a communication block and an audio unit.

14. The sensor according to claim 12 and wherein said processing unit comprises means to shut off said photo sensor array between measurements of a series.

15. The sensor according to claim 1 and also comprising non-battery means for supplying power.

16. The sensor according to claim 15 and wherein said non-battery means comprises at least one of: hand movement charging, solar batteries and thermoelectric devices utilizing body heat.
